(19) United States
(12) Patent Application Publication
(10) Pub. No.: US 2025/0046659 A1
(43) Pub. Date: Feb. 6, 2025

(54) SEMICONDUCTOR PACKAGES

(71) Applicant: Samsung Electronics Co., Ltd., Suwon-si (KR)

(72) Inventors: Se Ra Lee, Suwon-si (KR); Jun Yeong Heo, Suwon-si (KR); Yeong Kwon Ko, Suwon-si (KR)

(21) Appl. No.: 18/671,011

(22) Filed: May 22, 2024

(30) Foreign Application Priority Data
Aug. 2, 2023 (KR) 10-2023-0100944
Aug. 17, 2023 (KR) 10-2023-0107684

(51) Int. Cl. H01L 21/66; H01L 21/78; H01L 23/00

(52) U.S. Cl. CPC H01L 22/32; H01L 24/05; H01L 24/06; H01L 24/13; H01L 24/14; H01L 21/78; H01L 24/17; H01L 2224/05082; H01L 2224/05124; H01L 2224/05139; H01L 2224/05144; H01L 2224/05147; H01L 2224/05155; H01L 2224/05166; H01L 2224/05184; H01L 2224/0557; H01L 2224/05573; H01L 2224/05647; H01L 2224/05666; H01L 2224/05684; H01L 2224/06152; H01L 2224/06181; H01L 2224/13082; H01L 2224/13105; H01L 2224/13109; H01L 2224/13111; H01L 2224/13123; H01L 2224/13124; H01L 2224/13138; H01L 2224/13139; H01L 2224/13144; H01L 2224/13147; H01L 2224/13149; H01L 2224/13155; H01L 2224/13157; H01L 2224/13166; H01L 2224/13176; H01L 2224/1318; H01L 2224/13181; H01L 2224/13183; H01L 2224/13184; H01L 2224/14152; H01L 2224/16145; H01L 2224/16227; H01L 2224/17181; H01L 2924/01004; H01L 2924/0132

(57) ABSTRACT

A semiconductor package, which may include a semiconductor chip including a first surface and a second surface, which may be opposite to each other in a first direction. The semiconductor package may include a plurality of first bumps in a first area on the first surface and arranged along a second direction that intersects with the first direction, a plurality of second bumps in a second area on the first surface and arranged along the second direction and spaced apart from the plurality of first bumps in a third direction that intersects with the first direction and the second direction, a first test pad in a third area between the first area and the second area, and a third bump on the first test pad. The first test pad may be along an edge of the semiconductor chip in the third direction.

### CROSS-REFERENCE TO RELATED APPLICATIONS

This application claims priority from Korean Patent Application No. 10-2023-0100944, filed on Aug. 2, 2023, and Korean Patent Application No. 10-2023-0107684, filed on Aug. 17, 2023, both in the Korean Intellectual Property Office, and all the benefits accruing therefrom under 35 U.S.C. § 119, and the entire contents of the above-identified applications are incorporated by reference herein.

### BACKGROUND

### Technical Field

The present disclosure relates to semiconductor packages.

### Description of the Related Art

With the miniaturization and increase in processing speed of semiconductor devices, semiconductor packages that stack multiple semiconductor chips have been proposed. Particularly, according to recent trends, a thickness of a semiconductor substrate may be gradually thinner, which may realize high-stage stack tendency in a multi-stage stack structure oriented toward a through silicon via (TSV). Stealth dicing techniques have been applied to cut such a thin semiconductor substrate into individual semiconductor chip units. As the thickness of the semiconductor substrate becomes thinner, the possibility of bending in the semiconductor substrate during a stealth dicing process may be increased.

### BRIEF SUMMARY

An object of the present disclosure is to provide semiconductor packages in which reliability is improved.

The objects of the present disclosure are not limited to those mentioned above and additional objects of the present disclosure, which are not mentioned herein, will be clearly understood by those skilled in the art from the following description of the present disclosure.

According to some aspects of the present disclosure, there is a provided semiconductor package comprising a semiconductor chip including a first surface and a second surface, which are opposite to each other in a first direction, a plurality of first bumps in a first area on the first surface, the plurality of first bumps arranged along a second direction that intersects with the first direction, a plurality of second bumps in a second area on the first surface, the plurality of second bumps arranged along the second direction and spaced apart from the plurality of first bumps in a third direction that intersects with the first direction and the second direction, a first test pad in a third area on the first surface between the first area and the second area, and a third bump on the first test pad, wherein the first test pad is along an edge of the semiconductor chip in the third direction.

According to some aspects of the present disclosure, there is a provided semiconductor package comprising a semiconductor chip including a first surface and a second surface, which are opposite to each other in a first direction, a test pad on the first surface, a first bump on the test pad, a second bump on the first surface and spaced apart from the first bump in a second direction that intersects with the first direction, and a third bump on the first surface and spaced apart from the first bump in a direction opposite to the second direction, wherein the first surface includes a first area that extends in a third direction that intersects with the first direction and the second direction, a second area that extends in the third direction and is spaced apart from the first area in the second direction, and a third area that extends in the third direction and is between the first area and the second area. The first bump, the second bump and the third bump are in the third area, the second area and the first area, respectively, and the test pad is along an edge of the semiconductor chip in the second direction.

According to some aspects of the present disclosure, there is a provided a semiconductor package comprising a base substrate, a first semiconductor chip on the base substrate, including a first surface facing the base substrate and a second surface opposite to the first surface in a first direction, a plurality of second semiconductor chips on the first semiconductor chip, each second semiconductor chip including a third surface and a fourth surface opposite to the third surface in the first direction, the fourth surface being at a level farther than the third surface from the base substrate in the first direction, and a first bump group between the base substrate and the first semiconductor chip, wherein the first bump group includes first bumps spaced apart from each other in a second direction that intersects with the first direction, and a second bump between the first bumps, wherein the second bump is on a first test pad on the first surface, and wherein the first test pad is along an edge of the first semiconductor chip in the second direction.

It should be noted that the effects of the present disclosure are not limited to those described above, and other effects of the present disclosure will be apparent from the following description.

### BRIEF DESCRIPTION OF THE DRAWINGS

FIG. 1 is a schematic plan view illustrating a semiconductor package according to some embodiments.

FIG. 2 is a cross-sectional view taken along line I-I of FIG. 1.

FIG. 3 is an enlarged view illustrating an area II of FIG. 2.

FIG. 4 is a view illustrating a semiconductor package according to some embodiments.

FIGS. 5 and 6 are views illustrating a substrate processing method according to some embodiments.

FIG. 7 is a view illustrating a semiconductor package according to some embodiments.

FIG. 8 is a view illustrating a semiconductor package according to some embodiments.

FIG. 9 is a flow chart illustrating an example of a method for fabricating a bump of a semiconductor package according to some embodiments.

FIGS. 10 to 19 are views illustrating intermediate steps to describe a example of a method for fabricating bumps of a semiconductor package according to some embodiments.

### DETAILED DESCRIPTION OF THE DISCLOSURE

Hereinafter, a semiconductor package according to some embodiments will be described with reference to the accompanying drawings.

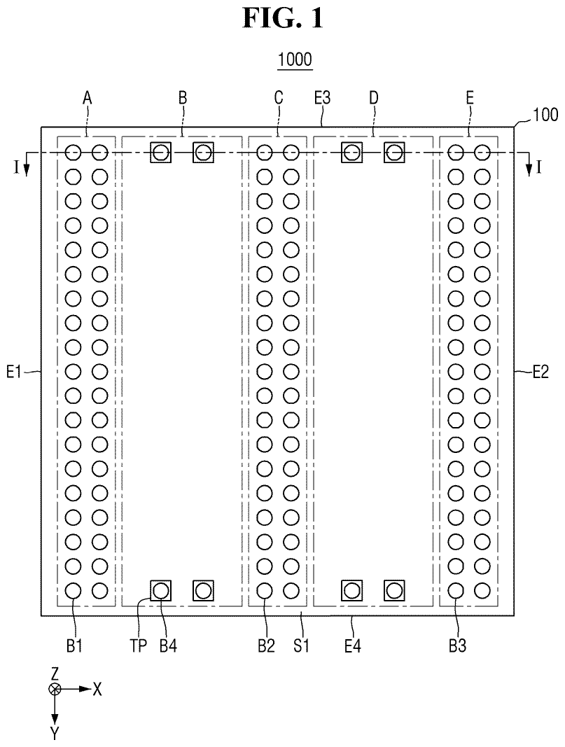

FIG. 1 is a schematic plan view illustrating a semiconductor package according to some embodiments.

Referring to FIG. 1, a semiconductor package 1000 may include a semiconductor chip 100, bumps B1, bumps B2, bumps B3, test pads TP and bumps B4.

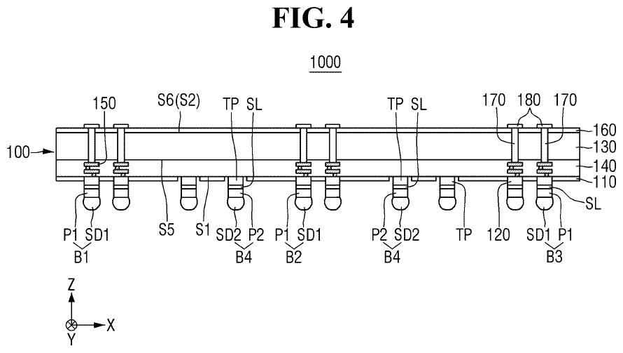

The semiconductor chip 100 may include two surfaces opposite to each other in a first direction Z, for example, a frontside and a backside. In FIG. 1, a first surface S1 may depict a frontside of the semiconductor chip 100. In some embodiments, the semiconductor package 1000 may be a flip-chip package. An internal configuration of the semiconductor chip 100 will be described in detail with reference to FIG. 4, and the description of FIG. 1 will be based on the configuration on the first surface S1 of the semiconductor chip 100.

The first surface S1 of the semiconductor chip 100 may include a plurality of areas A, B, C, D and E. The plurality of areas A, B, C, D and E may be distinguished and separated from one another. The plurality of areas A, B, C, D and E may be extended (e.g., extended in length) in a second direction Y. The areas A, C and E may be spaced apart from one another in a third direction X. The second direction Y and the third direction X may be horizontal directions that intersect each other and intersect the first direction Z. The area B may be between the area A and the area C, and the area D may be between the area C and the area E.

The semiconductor chip 100 may have a rectangular shape, and may include four edges E1, E2, E3 and E4. The edges E1 and E2 of the semiconductor chip 100 may be extended in length in the second direction Y, and may be spaced apart from each other in the third direction X. The edges E3 and E4 of the semiconductor chip 100 may be extended in length in the third direction X, and may be spaced apart from each other in the second direction Y.

The bumps B1 may be arranged in the second direction Y along the edge E1 of the semiconductor chip 100, and may be in the area A. The bumps B3 may be arranged in the second direction Y along the edge E2 of the semiconductor chip 100, and may be in the area E. The bumps B2 may be arranged in the second direction Y between the bumps B1 and the bumps B3, and may be in the area C.

The bumps B1, B2 and B3 may constitute an array structure having columns and rows as a whole. Although FIG. 1 illustrates that the bumps B1, B2 and B3 are respectively arranged in two columns, the present disclosure is not limited thereto, and various modifications may be made in the number and arrangement type of the bumps B1, B2 and B3 respectively included in the areas A, C and E depending on the embodiments.

In some embodiments, an interval between the bumps B1 in the area A in the second direction Y, an interval between the bumps B2 in the area C in the second direction Y or an interval between the bumps B3 in the area E in the second direction Y may be 0.46 mm, but the present disclosure is not limited thereto. Also, in some embodiments, the shortest distance between the bumps B1 in the area A and the bumps B2 in the area C in the third direction X or the shortest distance between the bumps B2 in the area C and the bumps B3 in the area E in the third direction X may be 2.5 mm, but the present disclosure is not limited thereto.

The bumps B1, B2 and B3 may be connection bumps for electrically connecting the semiconductor chip 100 to an external device or thermal bumps for discharging heat generated from the semiconductor chip 100 to a location outside the semiconductor chip 100. Alternatively, the bumps B1, B2 and B3 may be configured in a combination of connection bumps and thermal bumps. In some embodiments, the bumps B1, B2 and B3 may include a conductive material having high electrical conductivity and thermal conductivity.

The test pads TP may be in the area B between the bumps B1 and the bumps B2 or in the area D between the bumps B2 and the bumps B3. In FIG. 1, four test pads TP are shown as being in each of the areas B and D, but the present disclosure is not limited thereto. Various modifications may be made in the number of the test pads TP disposed between the bumps B1 and the bumps B2 or between the bumps B2 and the bumps B3 depending on the embodiments.

Each test pad TP may be along the edge E3 or the edge E4 of the semiconductor chip 100. For example, each test pad TP may be formed in an area relatively adjacent to the edge E3 or the edge E4 of the semiconductor chip 100, which may correspond to an outer portion of the semiconductor chip 100, among the areas on the first surface S1 of the semiconductor chip 100, but the present disclosure is not limited thereto. For example. In some embodiments the test pads TP may be formed in any portion inside the areas B and D, in which the bumps B1, B2 and B3 are not formed, among the areas on the first surface S1 of the semiconductor chip 100. For example, a first portion of the test pads TP may be along the edge E3 or the edge E4 of the semiconductor chip 100, and a second portion of the test pads TP may be in a central part of the areas inside the areas B and D.

Also, as shown in FIG. 1, when there is a plurality of test pads TP, the plurality of test pads TP may be arranged to be aligned in the third direction X along the edge E3 or the edge E4 of the semiconductor chip 100.

The test pads TP may be pads for testing characteristics of the semiconductor chip 100. For example, the test pads TP may be electrical die sorting (EDS) test pads for testing electrical characteristics of the semiconductor chip 100, but the present disclosure is not limited thereto. The test pads TP may be test pads which are on the first surface S1 of the semiconductor chip 100 and used to test characteristics of the semiconductor chip 100 or for other purposes and onto which connection bumps and/or thermal bumps, such as the bumps B1, B2 and B3, are not attached. The test pads TP may include a metal, such as nickel (Ni), copper (Cu), gold (Au), silver (Ag), aluminum (Al), tungsten (W) or titanium (Ti), or an alloy of one or more metals.

The bumps B4 may be formed on the test pads TP, respectively. The bumps B4 may be also between the bumps B1 and the bumps B2 or between the bumps B2 and the bumps B3. In this way, the test pads TP and the bumps B4 may be formed in an area on the first surface S1 of the semiconductor chip 100, in which the bumps B1, B2 and B3 corresponding to the connection bumps and/or the thermal bumps are not formed.

In FIG. 1, the bumps B4 are shown as being formed on all test pads TP, but the present disclosure is not limited thereto. For example, in some embodiments, the bumps B4 may be formed only on some of the test pads TP on the first surface S1 of the semiconductor chip 100.

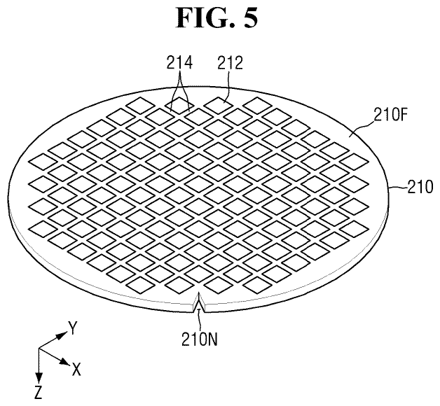

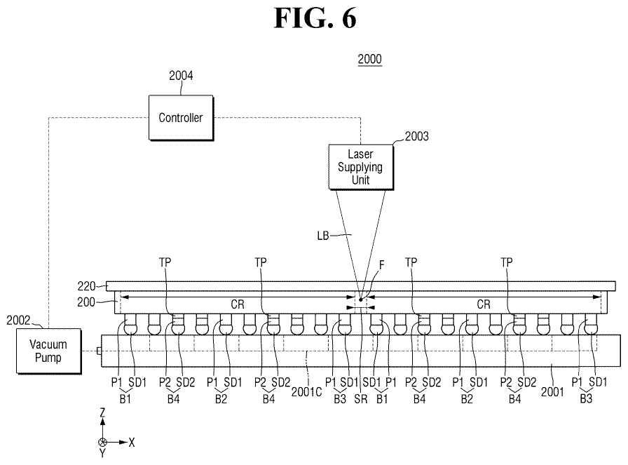

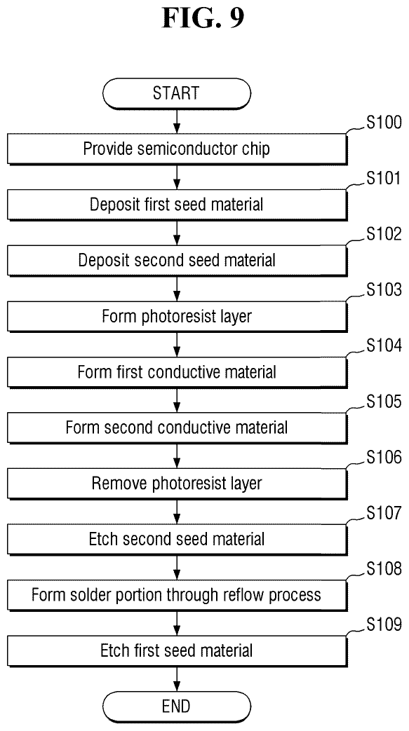

The bumps B4 may be support bumps rather than connection bumps or thermal bumps. Therefore, the bumps B4 may not be electrically connected to the test pads TP. For example, when a dicing process in which a semiconductor wafer is separated into structures of a single chip unit (for example, the semiconductor chip 100) is performed, the bumps B4 may serve to support the semiconductor wafer in order to prevent the semiconductor wafer from being bent. The dicing process will be described later with reference to FIGS. 5 and 6. The bumps B4 may include the same material as that of the bumps B1, B2 and B3, and may be formed in or during the same process step as that of the bumps B1, B2 and B3. A method for fabricating the bumps B1, B2, B3 and B4 will be described later with reference to FIGS. 9 to 19.

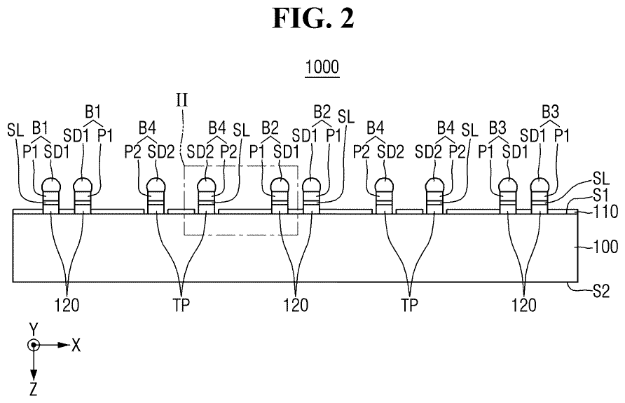

FIG. 2 is a cross-sectional view taken along line I-I of FIG. 1. Referring to FIG. 2, the semiconductor package 1000 may include a passivation layer 110 formed on the first surface S1 of the semiconductor chip 100. The passivation layer 110 may surround and/or conform to the first surface S1 of the semiconductor chip 100, and may protect the first surface S1 of the semiconductor chip 100. In some embodiments, the passivation layer 110 may include an insulating material such as an insulating polymer. Alternatively, the passivation layer 110 may be formed of a multi-layer that includes different materials (for example, silicon oxide (SiO₂) and silicon nitride (SiN)).

A portion of the first surface S1 of the semiconductor chip 100 may not be surrounded by the passivation layer 110, or may be free from overlap by the passivation layer 110. For example, an area, in which the bumps B1, B2, B3 and B4 are not formed, among the areas on the first surface S1 of the semiconductor chip 100 may be overlapped or covered by the passivation layer 110. An area adjacent to the area in which the bumps B4 are formed may be free from overlap by the passivation layer 110 and exposed to the outside without being covered by the passivation layer 110.

A second surface S2 of the semiconductor chip 100 may be opposite to the first surface S1 in the first direction Z. For example, the second surface S2 may be the backside of the semiconductor chip 100. Hereinafter, the bumps B1, B2 and B3 have the same configuration, and thus the description of the bumps B2 and B3 will be omitted in favor of the description of the bumps B1. The bumps B1 may be formed on a connection pad 120 formed on the first surface S1 of the semiconductor chip 100. A portion of sides of the connection pad 120 may be surrounded by the passivation layer 110, and the passivation layer 110 may expose the connection pad 120 to the outside. In some embodiments, a length or thickness of the connection pad 120 in the first direction Z may be greater than that of the passivation layer 110 in the first direction Z.

The bumps B1 may include a pillar portion P1 and a solder portion SD1. The pillar portion P1 may be formed on the connection pad 120, and the solder portion SD1 may be formed on the pillar portion P1. One end of the pillar portion P1 may be in contact with a seed layer SL, and the other end of the pillar portion P1 may be in contact with the solder portion SD1.

The pillar portion P1 may have a cylindrical or polygonal pillar shape, and the solder portion SD1 may have a hemispherical shape or a spherical shape. Each of the pillar portion P1 and the solder portion SD1 may include, but is not limited to, a metal, such as nickel (Ni), copper (Cu), gold (Au), silver (Ag), aluminum (Al), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga) or ruthenium (Ru), or an alloy of one or more metals.

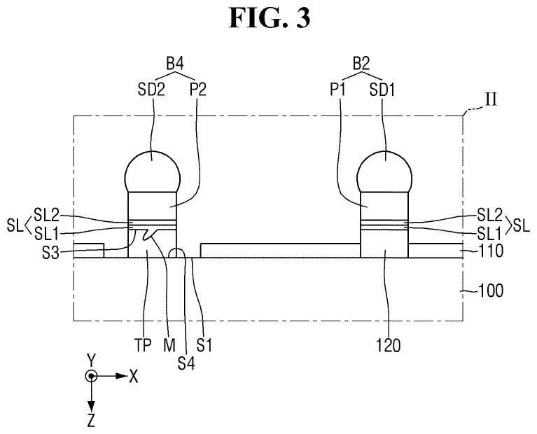

The bumps B4 may include a pillar portion P2 and a solder portion SD2. The pillar portion P2 may be formed on the test pad TP on the first surface S1 of the semiconductor chip 100, and the solder portion SD2 may be formed on the pillar portion P2. One end of the pillar portion P2 may be in contact with a seed layer SL, and the other end of the pillar portion P2 may be in contact with the solder portion SD2. The description of the shape and material of the pillar portion P2 and the solder portion SD2 is repeated with that of the shape and material of the pillar portion P1 and the solder portion SD1, and thus will be omitted below. The seed layer SL formed between the connection pad 120 and the bumps B1, B2 and B3 and the seed layer SL formed between the test pad TP and the bumps B4 will be described later in greater detail with reference to FIG. 3.

In some embodiments, upper surfaces of the bumps B1, B2 and B3 and an upper surface of the bumps B4 may at a same height or distance from the first surface S1 of the semiconductor chip 100. In this case, when referring to the upper surfaces of the bumps B1, B2, B3 and B4 it is assumed that an opposite direction of the first direction Z (e.g., from the second surface S2 to the first surface S1 of the semiconductor chip 100) is referred to as an upward direction and the first direction Z (e.g., from the first surface S1 to the second surface S2 of the semiconductor chip 100) is referred to as a downward direction. Also, the height refers to a maximum length in the first direction Z, which is perpendicular to the first surface S1 of the semiconductor chip 100. As the upper surfaces of the bumps B1, B2, B3 and the upper surface of the bumps B4 are at the same height from the first surface S1 of the semiconductor chip 100, when the semiconductor chip 100 is packaged on an external device such as a printed circuit board, the semiconductor chip 100 may be stably packaged.

In some embodiments, a length from the first surface S1 of the semiconductor chip 100 to the upper surfaces of the bumps B1, B2 and B3 may be longer than a length in the first direction Z from the first surface S1 of the semiconductor chip 100 to the upper surface of the bumps B4. For example, when the semiconductor chip 100 is packaged on the external device such as a printed circuit board, the bumps B1, B2 and B3 may be connection bumps electrically connected to the external device, and the bumps B4 may be bumps that are not electrically connected to the external device, or electrically isolated from the external device. When the semiconductor chip 100 is packaged on the external device and the bumps B1, B2 and B3 are electrically connected to the external device, the height of each of the bumps B1, B2 and B3 may be short. Therefore, the height of each of the bumps B1, B2 and B3 may be relatively longer than the height of the bumps B4 in the step of fabricating the bumps B1, B2, B3 and B4.

FIG. 3 is an enlarged view illustrating an area II of FIG. 2.

Referring to FIG. 3, the test pad TP may include a fourth surface S4 and a third surface S3, which face each other in the first direction Z. The fourth surface S4 of the test pad TP may be in contact with the first surface S1 of the semiconductor chip 100, and the third surface S3 of the test pad TP may be in contact with the seed layer SL. A test probing mark M may be formed on the third surface S3 of the test pad TP. The test probing mark M may be formed to be inserted into the test pad TP from the third surface S3.

For example, when an EDS test for testing electrical characteristics of the semiconductor chip 100 is performed before the semiconductor chip 100 is separated from the semiconductor wafer, the test probing mark M may be formed by contacting a probe needle in which an electrical signal is applied to the test pad TP. After the test is completed, in an operation of fabricating the semiconductor package 1000 (shown in FIG. 2), a first seed layer SL1 may be formed to fill a lead-in portion of the test probing mark M (in other words, an inlet of the test probing mark M) while the bump B4 is being formed on the test pad TP.

The seed layers SL may be formed between the test pad TP and the pillar portion P2 and between the connection pad 120 and the pillar portion P1. The seed layers SL may include a first seed layer SL1 on the test pad TP or the connection pad 120, and a second seed layer SL on the first seed layer SL1. The seed layers SL may serve to prevent the bumps B1, B2, B3 and B4 from being separated from the semiconductor chip 100 by impact applied to the bumps B1, B2, B3 and B4. The first seed layer SL1 and the second seed layer SL2 may include two different materials selected from titanium (Ti), copper (Cu) and titanium tungsten (TiW). For example, the first seed layer SL1 and the second seed layer SL2 may be formed of a double layer such as Ti/Cu or TiW/Cu. Operations to fabricate the first seed layer SL1 and the second seed layer SL2 will be described later with reference to FIG. 9.

FIG. 4 is a view illustrating a semiconductor package according to some embodiments. FIG. 4 illustrates a detailed configuration of the semiconductor package 1000 shown in FIGS. 1 and 2. Hereinafter, at least some description repetitive to that provided previously will be omitted, and the following description will be based on differences from the previously-provided description. Also, in the following description, an upper surface or a lower surface may be based on the first direction Z.

Referring to FIG. 4, the semiconductor package 1000 may include a semiconductor substrate 130, a semiconductor device layer 140, a multilayer wiring pattern 150, passivation layers 110 and 160, a through electrode 170, connection pads 120 and 180, test pads TP, and bumps B1, B2, B3 and B4. The semiconductor package 1000 may include a semiconductor chip 100, which may include the semiconductor substrate 130, the semiconductor device layer 140, the multilayer wiring pattern 150 and the through electrode 170.

The semiconductor substrate 130 may include a fifth surface S5 and a sixth surface S6, which are opposite to each other in the first direction Z. For example, the fifth surface S5 may be the frontside of the semiconductor substrate 130, and the sixth surface S6 may be the backside of the semiconductor substrate 130. The sixth surface S6 of the semiconductor substrate 130 may be the same plane as the second surface S2 of the semiconductor chip 100. The semiconductor substrate 130 may include a semiconductor element, such as germanium (Ge), and/or a compound, such as silicon carbide (SiC), gallium arsenide (GaAs), indium arsenide (InAs) and indium phosphide (InP). However, the material of the semiconductor substrate 130 is not limited to those described above.

The semiconductor device layer 140 may be formed on the fifth surface S5 of the semiconductor substrate 130. The semiconductor device layer 140 may include various types of individual devices and an interlayer insulating layer. For example, the individual devices may include a variety of microelectronic devices, for example, a complementary metal-oxide semiconductor (CMOS) transistor, a metal-oxide-semiconductor field effect transistor (MOSFET) a system large scale integration (LSI), an image sensor such as a CMOS imaging sensor (CIS), a micro-electromechanical system (MEMS), an active device, a passive device or the like.

The semiconductor device layer 140 may include a memory device and/or a logic device. The memory device may constitute a volatile memory device and/or a non-volatile memory device. The volatile memory device may include existing volatile memory devices, such as a dynamic random access memory (DRAM), a static RAM (SRAM), a thyristor RAM (TRAM), a zero capacitor RAM (ZRAM) or a Twin Transistor RAM (TTRAM), and/or other volatile memory devices developed or in development. Also, the non-volatile memory device may include existing non-volatile memory devices, such as a flash memory, a magnetic RAM (MRAM), a spin-transfer torque MRAM (STT-MRAM), a ferroelectric RAM (FRAM), a phase change RAM (PRAM), a resistive RAM (RRAM), a nanotube RRAM, a polymer RAM, a nano floating gate memory, a holographic memory, a molecular electronics memory or an insulator resistance change memory, and/or other non-volatile memory devices developed or in development.

The logic device may be implemented by, for example, a microprocessor, a graphics processor, a signal processor, a network processor, an audio codec, a video codec, an application processor or a system on chip, but the present disclosure is not limited thereto. The microprocessor may include, for example, a single core or a multi-core.

The multilayer wiring pattern 150 may include a plurality of wiring patterns positioned at different height levels. At least a portion of the multilayer wiring pattern 150 may be in the semiconductor device layer 140. In addition, at least a portion of the multilayer wiring pattern 150 may be embedded in the semiconductor device layer 140. The multilayer wiring pattern 150 may be connected to the through electrode 170 and the connection pad 120 to electrically connect the through electrode 170 with the connection pad 120. The multilayer wiring pattern 150 may include a conductive material.

The passivation layer 110 may surround a lower surface of the semiconductor device layer 140 and the sides of the connection pad 120, and may protect the semiconductor device layer 140 and the connection pad 120. That is, the passivation layer 110 may be a lower passivation layer for protecting a lower portion of the semiconductor chip 100. The passivation layer 110 may expose the connection pad 120 and the test pad TP to a location outside the semiconductor package 1000. The passivation layer 160 may be formed on the sixth surface S6 of the semiconductor substrate 130. The passivation layer 160 may be an upper passivation layer for protecting an upper portion of the semiconductor chip 100. The passivation layer 160 may surround at least a portion of sides of the through electrode 170 to protect the through electrode 170. In the same manner as the passivation layer 110, the passivation layer 160 may include an insulating material such as an insulating polymer, or may be formed of a multi-layer that includes silicon oxide and/or silicon nitride.

The through electrode 170 may penetrate or extend through at least a portion of the semiconductor chip 100 in the first direction Z. The through electrode 170 may be connected to the connection pad 180 and the multilayer wiring pattern 150 and may electrically connect the connection pad 180 with the multilayer wiring pattern 150.

The connection pad 120 may be formed on the first surface S1 of the semiconductor chip 100, and the connection pad 120 may be exposed by the passivation layer 110 and thus connected to the bumps B1, B2 and B3. The connection pad 120 may include a metal, such as nickel (Ni), copper (Cu), gold (Au), silver (Ag), aluminum (Al), tungsten (W) or titanium (Ti), or alloy of one or more metals.

The connection pad 180 may be formed on the passivation layer 160, and may be electrically connected to the through electrode 170. The connection pad 180 may be electrically connected to a connection terminal (for example, bump) of an external device (not shown in FIG. 3). The description of a material included in the connection pad 180 may the same as that of the material included in the connection pad 120 and thus will be omitted here in the interest of brevity.

The bumps B1, B2 and B3 may be electrically connected to the connection pad 120, the multilayer wiring pattern 150, the through electrode 170 and the connection pad 180, but the test pads TP and the bumps B4 on the test pads TP may not be electrically connected to the through electrode 170 and the connection pad 180. That is, the bumps B4 may not be connection bumps for electrically connecting the semiconductor chip 100 to the external device. In some embodiments, the test pads TP may be connected with a redistribution layer of the semiconductor chip 100.

FIGS. 5 and 6 are exemplary views illustrating a substrate processing method according to some embodiments.

First, referring to FIG. 5, a substrate 210 may be a semiconductor substrate. The substrate 210 may be a semiconductor wafer, and may have a circular shape when viewed in a plan view. The substrate 210 may have a notch 210N used as a reference display for alignment of the substrate 210. The substrate 210 may include silicon. Alternatively, the substrate 210 may include a semiconductor element such as germanium, or a compound semiconductor such as silicon carbide (SiC), gallium arsenide (GaAs), indium arsenide (InAs) and indium phosphide (InP). Alternatively, the substrate 210 may have a silicon on insulator (SOI) structure.

In some embodiments, the substrate 210 may include a well doped with impurities or a structure doped with impurities, which may be a conductive area. In addition, the substrate 200 may have various device isolation structures such as a shallow trench isolation (STI) structure. It is assumed that the substrate 210 has a diameter of 12 inches, approximately, and a case that a silicon wafer is used will be described. However, a person with ordinary skill will understand that a substrate 210 having a diameter smaller or greater than 12 inches may be used and a substrate 210 made of a material other than silicon may be used.

The substrate 210 may include an active surface 210F and a non-active surface 210B, which are opposite to each other in the first direction Z. The semiconductor device layer 140 of FIG. 4 may be formed on the active surface 210F of the substrate 210. The semiconductor device layer 140 may include an insulating layer and/or a conductive layer, which may be provided on the active surface 210F of the substrate 210. The semiconductor device layer 140 may include a semiconductor device and a metal interconnect structure.

The substrate 210 may include integrated circuit areas 212 and a cutting area 214 that separates the integrated circuit areas 212. The cutting area 214 may be referred to as a scribe line. The cutting area 214 may be in the form of a straight line having a constant width. Each of the integrated circuit areas 212 may be surrounded by the cutting area 214 when viewed from a plan view. As described below, the substrate 210 and various kinds of material films formed on the substrate 210 may be cut by a cutting process (dicing process) performed along the cutting area 214, whereby the integrated circuit areas 212 may be separated into a plurality of semiconductor chips, respectively.

The semiconductor chip 100 shown in FIGS. 1 to 4 may be one of a plurality of semiconductor chips separated by performing a dicing process for the substrate 210. Before the dicing process is performed, in the step of fabricating the substrate 210, the test pads TP and the bumps B4, which are shown in FIGS. 1 to 4, may be formed in the integrated circuit areas 212, respectively. Hereinafter, a method for cutting the substrate 210 through a stealth dicing process for the substrate 210 will be described by way of example.

Next, referring to FIG. 6, a substrate processing apparatus 2000 may be configured to perform a dicing process of separating the substrate 200, which is a workpiece and which may correspond to the substrate 210 of FIG. 5, into structures of a single chip unit. The substrate 200 may include chip areas CR and a scribe area SR. The chip areas CR may correspond to the integrated circuit areas 212 of FIG. 5, and the scribe area SR may correspond to the cutting area 214 of FIG. 5. The substrate processing apparatus 2000 may separate the substrate 200 into a plurality of semiconductor chips by irradiating a laser beam LB to a light condensing point F inside the scribe area SR between the chip areas CR. At this time, each separated semiconductor chip may correspond to the semiconductor chip 100 shown in FIGS. 1 to 4.

In some embodiments, the substrate processing apparatus 2000 may be configured to perform a laser dicing process of cutting the substrate 200 by using the laser beam LB. In some embodiments, the substrate processing apparatus 2000 may be configured to perform a stealth dicing process of forming a reforming layer inside the substrate 200 by condensing the laser beam LB inside the substrate 200 and cutting the substrate 200 with a crack induced from the reforming layer.

The substrate processing apparatus 2000 may include a chuck table 2001 configured to support the substrate 200, a vacuum pump 2002, a laser supplying unit 2003, and a controller 2004.

The chuck table 2001 may be configured to perform a chucking operation of applying an external force to the substrate 200 such that the substrate 200 is attached onto the chuck table 2001 or a dechucking operation of releasing or terminating the external force for the substrate 200 such that the substrate 200 may be separated from the chuck table 2001.

The chuck table 2001 may be configured to vacuum-adsorb the substrate 200. An upper surface of the chuck table 2001 may be a vacuum-adsorbed surface, and the chuck table 2001 may include vacuum channels 2001C that extend from the upper surface of the chuck table 2001 to the inside of the chuck table 2001. The vacuum channels 2001C may be exposed through the upper surface of the chuck table 2001. The vacuum channels 2001C may be distributed generally evenly on the upper surface of the chuck table 2001.

The vacuum pump 2002 may be connected with the vacuum channels 2001C of the chuck table 2001 to apply a vacuum pressure to the vacuum channels 2001C. Therefore, the substrate 200 may be vacuum-adsorbed on the chuck table 2001. For example, when the vacuum pump 2002 applies a vacuum pressure to the vacuum channels 2001C, a pressure lower than an ambient pressure may be formed on one surface of the substrate 200 facing the upper surface of the chuck table 2001 so that the substrate 200 may be vacuum-adsorbed on the chuck table 2001. In addition, the vacuum pump 130 may release or terminate the vacuum pressure in the vacuum channels 2001C so that the substrate 200 may be separated from the chuck table 2001.

The laser supplying unit 2003 may be provided on or above the chuck table 2001, and may irradiate the laser beam LB downward toward the substrate 200 mounted on the chuck table 2001. The laser supplying unit 2003 may be configured to generate the laser beam LB having characteristics suitable for processing the substrate 200 that is a workpiece. For example, a wavelength, a pulse width, an output, etc. of the laser beam LB output from the laser supplying unit 2003 may adjusted depending on the material and thickness of the substrate 200. In some embodiments, the laser supplying unit 2003 may output the laser beam LB having a wavelength band of infrared light.

The controller 2004 may control the overall process using the substrate processing apparatus 2000. The controller 2004 may be implemented in hardware, firmware, software or any combination thereof. For example, the controller 2004 may be a computing device such as a workstation computer, a desktop computer, a laptop computer or a tablet computer. For example, the controller 2004 may include a memory device such as a read only memory (ROM) and a random access memory (RAM), in which various programming instructions are stored, and a processor, such as a microprocessor, a central processing unit (CPU) and a graphics processing unit (GPU), configured to process the programming instructions stored in the memory device and/or signals provided from an external device. In addition, the controller 2004 may include a receiver and a transmitter for receiving and transmitting electrical signals. In some embodiments, the controller 2004 may perform auto focusing for adjusting automatically the position of the light condensing point F of the laser beam LB output from the laser supplying unit 2003.

In this way, in a state where the substrate 200 is vacuum-adsorbed on the chuck table 2001, when the substrate 200 is diced in an individual chip unit by irradiating the laser beam LB to transmit a dicing tape 220 attached onto the upper surface of the substrate 200, the test pads TP may be among the bumps B1, B2 and B3 of the substrate 200, which may be spaced apart from one another in the third direction X, and the bumps B4 may be on the test pads TP.

The bumps B4 may provide structural stability so that the substrate 200 is not bent when the substrate 200 is vacuum-adsorbed on the chuck table 2001. That is, the bumps B4 may be attached to the test pads TP on the lower surface of the substrate 200, so that an area in which the bump is not formed on the surface of the substrate 200 facing the chuck table 2001 may be reduced, whereby characteristics related to the location where the laser beam is irradiated to the surface of the substrate 200 in the stealth dicing process using the laser beam LB may be improved. That is, the bumps B4 serving to support the substrate 200 during the dicing process may be formed on the test pads TP which are not used in a subsequent process for packaging the substrate 200 after dicing the substrate 200, so that position distribution of the light condensing point F in the first direction Z, to which the laser beam LB is irradiated, may be uniformly set over the entire surface of the substrate 200. In other words, the fact that the positional distribution of the light condensing point F to which the laser beam LB is irradiated is set uniformly over the entire surface of the substrate 200 in the first direction Z may mean that the follow-up capability of the surface of the substrate 200 has been improved.

Referring back to FIG. 1, the edges E1, E2, E3 and E4 of the semiconductor chip 100 may be adjacent to the cutting area 214 of FIG. 5, that is, the scribe area SR of FIG. 6. At this time, the test pads TP and the bumps B4 formed on the test pads TP may be along the edges E3 and E4 of the semiconductor chip 100, so that the portions of the edges E3 and E4 of the semiconductor chip 100, at which the bending phenomenon of the substrate 200 occurs most severely, may be supported by the bumps B4 during the dicing process of FIG. 6, whereby characteristics related to the location where the laser beam is irradiated to the surface of the substrate 200, to which the laser beam LB is irradiated, may be improved.

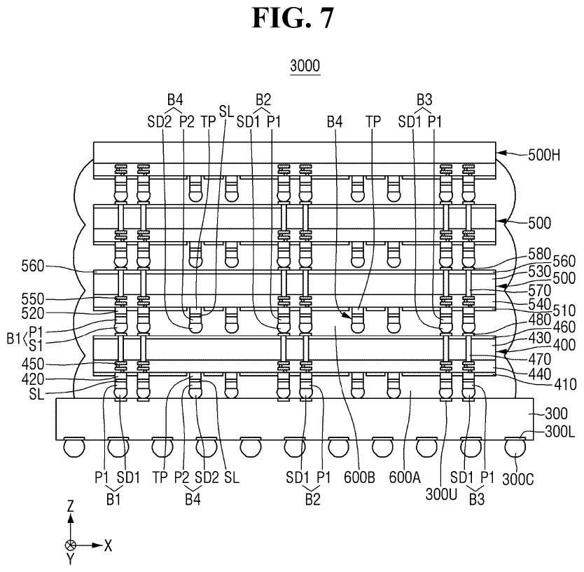

FIG. 7 is a view illustrating a semiconductor package according to some embodiments. Hereinafter, at least description that is repetitive of the previously provided description will be omitted, and the following description will be based on differences from the previously provided description. In the following description, an upper surface or a lower surface may be based on the first direction Z.

First, referring to FIG. 7, a semiconductor package 3000 may include a base substrate 300, a first semiconductor chip 400, a plurality of second semiconductor chips 500, and adhesive layers 600A and 600B. The first semiconductor chip 400 and the plurality of second semiconductor chips 500 may be stacked on the base substrate 300 in the first direction Z. A second semiconductor chip 500H may be a semiconductor chip, which may be at the uppermost end among the plurality of second semiconductor chips 500.

The base substrate 300 may be, for example, a printed circuit board (PCB) or an interposer. When the base substrate 300 is a printed circuit board, the base substrate 300 may include a lower pad 300L, an upper pad 300U, and a solder resist layer formed on a lower surface and an upper surface of the base substrate 300. An internal wiring (not shown) may be formed in a body portion of the base substrate 300 and may electrically connect the lower pad 300L with the upper pad 300U. The lower pad 300L and the upper pad 300U may be portions exposed by the solder resist layer among circuit wirings patterned on the lower surface and the upper surface of the base substrate 300.

When the base substrate 300 is an interposer, the base substrate 300 may be made of a semiconductor material, and may include a lower pad 300L and an upper pad 300U, which may be formed on the lower surface and the upper surface of the base substrate 300, respectively. The base substrate 300 may be formed from a semiconductor wafer, for example. The internal wiring may be formed on the lower surface, the upper surface or the inside of the base substrate 300. In addition, a through via may be formed inside the base substrate 300 and may electrically connect the lower pad 300L with the upper pad 300U.

An external connection terminal 300C may be attached to the lower surface of the base substrate 300. The external connection terminal 300C may be attached to the lower pad 300L. The external connection terminal 300C may be, for example, a solder ball or a bump. The external connection terminal 300C may electrically connect the semiconductor package 3000 with an external device (not shown).

The first semiconductor chip 400 may include a lower surface facing the upper surface of the base substrate 300 and an upper surface opposite to the lower surface in the first direction Z. The first semiconductor chip 400 may include a semiconductor substrate 430, a semiconductor device layer 440, a multilayer wiring pattern 450 and a through electrode 470. A passivation layer 410 may be formed on the lower surface of the first semiconductor chip 400, and a passivation layer 460 may be formed on the upper surface of the first semiconductor chip 400. Connection pads 420, seed layers SL, test pads TP, and a bump group which includes bumps B1, B2 and B3 and bumps B4, may be formed on the lower surface of the first semiconductor chip 400, and a connection pad 480 may be formed on the upper surface of the semiconductor chip first 400. The bump group may be between the base substrate 300 and the semiconductor chip 400.

The description of the semiconductor substrate 430, the semiconductor device layer 440, the multilayer wiring pattern 450, the through electrode 470, the passivation layers 410 and 460, the connection pads 420 and 480, the test pads TP, the seed layers SL, the bumps B1, B2, B3 and the bumps B4 of the first semiconductor chip 400 may be respectively the same as that of the semiconductor substrate 130, the semiconductor device layer 140, the multilayer wiring pattern 150, the through electrode 170, the passivation layers 110 and 160, the connection pads 120 and 180, the test pads TP, the seed layers SL, the bumps B1, B2 and B3 and the bumps B4, which are shown in FIGS. 1 to 4, and thus description thereof will be omitted here.

Each of the plurality of second semiconductor chips 500 may include a lower surface and an upper surface, which are opposite to each other in the first direction Z. Each of the plurality of second semiconductor chips 500 may include a semiconductor substrate 530, a semiconductor device layer 540, a multilayer wiring pattern 550 and a through electrode 570. A passivation layer 510 may be formed on the lower surface of each second semiconductor chip 500, and a passivation layer 560 may be formed on the upper surface of each second semiconductor chip 500. Connection pads 520, test pads TP, and a bump group which includes bumps B1, B2 and B3 and bumps B4, may be formed on the lower surface of each second semiconductor chip 500, and a connection pad 580 may be formed on the upper surface of each second semiconductor chip 500 (or each second semiconductor chip 500 other than the uppermost second semiconductor chip 500H). A bump group may be between the first semiconductor chip 400 and the second semiconductor chip 500 directly above the first semiconductor chip 400, or between each two second semiconductor chips 500.

The description of the semiconductor substrate 530, the semiconductor device layer 540, the multilayer wiring pattern 550, the through electrode 570, the passivation layers 510 and 560, the connection pads 520 and 580, the test pads TP, the seed layers SL, the bumps B1, B2, B3 and the bumps B4 of each second semiconductor chip 500 may be respectively the same as that of the semiconductor substrate 130, the semiconductor device layer 140, the multilayer wiring pattern 150, the through electrode 170, the passivation layers 110 and 160, the connection pads 120 and 180, the test pads TP, the seed layers SL, the bumps B1, B2 and B3 and the bumps B4, which are shown in FIGS. 1 to 4, and thus description thereof will be omitted here. However, the semiconductor chip 500H at the uppermost end may not include the through electrode 570 and the connection pad 580.

The bumps B1, B2, B3 and B4 between the first semiconductor chip 400 and the base substrate 300 may have the same arrangement type as that of the bumps B1, B2, B3 and B4 of the semiconductor package 1000 described with reference to FIGS. 1 to 4. For example, the bumps B1, B2 and B3 between the first semiconductor chip 400 and the base substrate 300 may be arranged in the second direction Y, and the bumps B1, B2 and B3 may be spaced apart from one another in the third direction X. The test pad TP formed on the lower surface of the semiconductor chip 400 and the bump B4 formed on the test pad TP may be arranged along the edge of the semiconductor chip 400 in the third direction X. That is, the test pad TP may be formed in an outer portion of the semiconductor chip 400 in the third direction X. In addition, when a plurality of test pads TP and a plurality of bumps B4 are provided between the first semiconductor chip 400 and the base substrate 300, the plurality of test pads TP and the plurality of bumps B4 may be aligned in the third direction X along the edge of the semiconductor chip 400 in the third direction X.

Likewise, the bumps B1, B2, B3 and B4 between a second semiconductor chip 500 and the first semiconductor chip 400 and the bumps B1, B2, B3 and B4 between each of the plurality of second semiconductor chips 500 may have the same arrangement type as that of the bumps B1, B2, B3 and B4 of the semiconductor package 1000 described with reference to FIGS. 1 to 4, and thus their repeated description will be omitted.

When the first semiconductor chip 400 and the plurality of second semiconductor chips 500 are stacked on the base substrate 300 in the first direction Z, the base substrate 300, the first semiconductor chip 400 and the plurality of second semiconductor chips 500 may be electrically connected to one another through the upper pad 300U, the bumps B1, B2 and B3, the connection pads 420, 480, 520 and 580, the multilayer wiring patterns 450 and 550 and the through electrodes 470 and 570. The bumps B4 may be attached onto the test pads TP to prevent the substrate 200 from being bent during the dicing process illustrated in FIG. 6 before the semiconductor package 3000 is fabricated by stacking the first semiconductor chip 400 and the plurality of second semiconductor chips 500 on the base substrate 300. Therefore, unlike the bumps B1, B2 and B3, the bumps B4 may not be electrically connected to the upper pad 300U, the connection pads 420, 480, 520 and 580 and the through electrodes 470 and 570. That is, unlike the bumps B1, B2 and B3, the bumps B4 may not serve to electrically connect the base substrate 300, the first semiconductor chip 400 and the plurality of second semiconductor chips 500 to one another.

The semiconductor package 3000 may further include an adhesive layer 600A and adhesive layers 600B. The adhesive layer 600A may be between the base substrate 300 and the first semiconductor chip 400. The adhesive layer 600A may surround the sides of the bumps B1, B2, B3 and the bumps B4, and may surround the sides of the connection pad 420 and the seed layer SL.

The adhesive layer 600B may be between the first semiconductor chip 400 and a second semiconductor chip 500 and between the second semiconductor chips 500. The adhesive layer 600B may surround the sides of the bumps B1, B2, B3 and the bumps B4, and may surround the sides of the connection pad 420 and the seed layer SL. According to some embodiments, as the first semiconductor chip 400 and the plurality of second semiconductor chips 500 are stacked on the base substrate 300, the adhesive layer 600A and the adhesive layers 600B may cover the sides of the first semiconductor chip 400 and the plurality of second semiconductor chips 500, respectively, and may be connected to each other on the sides of the first semiconductor chip 400 and the plurality of second semiconductor chips 500.

The first semiconductor chip 400 may be adhered to the base substrate 300 by the adhesive layer 600A, and the first semiconductor chip 400 may be adhered to the second semiconductor chip 500 by the adhesive layer 600B. In addition, the second semiconductor chips 500 may be adhered to each other by the adhesive layer 600B. The adhesive layers 600A and 600B may be non-conductive material layers of an epoxy-based material. For example, the adhesive layers 600A and 600B may be non-conductive films (NCF), but the present disclosure is not limited thereto.

In some embodiments, the first semiconductor chip 400 may not include a memory cell. The first semiconductor chip 400 may include a test logic circuit such as a serial-parallel conversion circuit, a design for test (DFT), a joint test action group (JTAG) and/or a memory built in self-test (MBIST), and/or a signal interface circuit such as PHY. Each of the plurality of second semiconductor chips 500 may include a memory cell. For example, the first semiconductor chip 400 may be a buffer chip configured to control the plurality of second semiconductor chips 500.

Each second semiconductor chip 500 may be a volatile memory, such as a Dynamic Random Access Memory (DRAM) or a Static Random Access Memory (SRAM), or a nonvolatile memory, such as a Phase-Change Random Access Memory (PRAM), a Magneto-Resistive Random Access Memory (MRAM), a Ferroelectric Random Access Memory (FeRAM) or a Resistive Random Access Memory (RRAM).

In some embodiments, the first semiconductor chip 400 and the plurality of second semiconductor chips 500 may constitute a high bandwidth memory (HBM). For example, the first semiconductor chip 400 may be a buffer chip for controlling an HBM DRAM, and the plurality of second semiconductor chips 500 may be memory cell chips having a cell of an HBM DRAM controlled by the first semiconductor chip 400. The first semiconductor chip 400 may be referred to as a buffer chip, a master chip or an HBM controller die, and the plurality of second semiconductor chips 500 may be referred to as memory chips, slave chips, DRAM dices or DRAM slices. The first semiconductor chip 400 and the plurality of second semiconductor chips 500 stacked on the first semiconductor chip 400 may be together referred to as HBM DRAM devices or HBM DRAM chips.

FIG. 7 illustrates that one semiconductor package 3000 includes one first semiconductor chip 400 and three second semiconductor chips 500, but one semiconductor package 3000 may include one first semiconductor chip 400 and e.g., four, eight, twelve or sixteen second semiconductor chips 500.

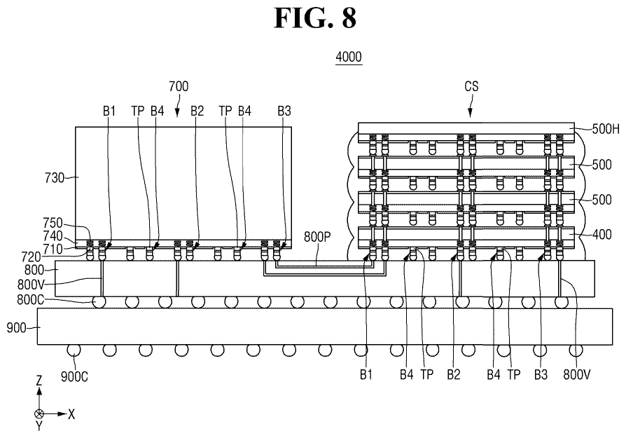

FIG. 8 is a view illustrating a semiconductor package according to some embodiments.

Referring to FIG. 8, a semiconductor package 4000 may include a third semiconductor chip 700, a stacked chip structure CS, an interposer substrate 800 and a packaging substrate 900. The stacked chip structure CS may correspond to the first semiconductor chip 400 and the plurality of second semiconductor chips 500 of the semiconductor package 3000, which are shown in FIG. 7. The third semiconductor chip 700 may be, for example, a processor unit. The third semiconductor chip 700 may be, for example, a micro processor unit (MPU) or a graphic processor unit (GPU), but the present disclosure is not limited thereto.

The third semiconductor chip 700, like the first semiconductor chip 400 and the second semiconductor chips 500, may be a semiconductor chip separated from the substrate 210 shown in FIG. 5 by the dicing process shown in FIG. 6.

The first semiconductor chip 700 may include a semiconductor substrate 730, a semiconductor device layer 740, a multilayer wiring pattern 750, a passivation layer 710, a connection pad 720, test pads TP, bumps B1, B2 and B3, and bumps B4. The description of the semiconductor substrate 730, the semiconductor device layer 740, the multilayer wiring pattern 750, the passivation layer 710, the connection pad 720, the test pads TP, the bumps B1, B2 and B3 and the bumps B4 of the third semiconductor chip 700 may be the same as that of the semiconductor substrate 130, the semiconductor device layer 140, the multilayer wiring pattern 150, the passivation layer 110, the connection pad 120, the test pads TP, the bumps B1, B2 and B3 and the bumps B4, which are shown in FIGS. 1 to 4, and thus description thereof will be omitted here.

The interposer substrate 800 may include an upper surface and a lower surface, which are opposite to each other in the first direction Z. The stacked chip structure CS and the third semiconductor chip 700 may be on the upper surface of the interposer substrate 800. The stacked chip structure CS and the third semiconductor chip 700 may be electrically connected to the interposer substrate 800.

The interposer substrate 800 may include a through via 800V and an inter-chip connection wiring 800P. The through via 800V and the inter-chip connection wiring 800P may be in the interposer substrate 800. The through via 800V may penetrate or extend through the interposer substrate 800. The through via 800V may electrically connect the bumps B1, B2 and B3 formed on the lower surface of the third semiconductor chip 700 and the bumps B1, B2 and B3 formed on the lower surface of the first semiconductor chip 400 included in the stacked chip structure CS to an external connection terminal 800C. The inter-chip connection wiring 800P may electrically connect the stacked chip structure CS and the third semiconductor chip 700 to each other by electrically connecting the bumps B1, B2 and B3 formed on the lower surface of the third semiconductor chip 700 with the bumps B1, B2 and B3 formed on the lower surface of the first semiconductor chip 400 included in the stacked chip structure CS.

The external connection terminal 800C may be between the interposer substrate 800 and the packaging substrate 900. The external connection terminal 800C may electrically connect the interposer substrate 800 with the packaging substrate 900.

The packaging substrate 900 may be on the lower surface of the interposer substrate 800. The packaging substrate 900 may include upper and lower surfaces opposite to each other in the first direction Z. The external connection terminal 900C may be attached onto the lower surface of the packaging substrate 900. The external connection terminal 900C may connect the semiconductor package 4000 to an external device (not shown).

In this way, the bumps B1, B2 and B3 formed on the lower surface of the third semiconductor chip 700 may electrically connect the third semiconductor chip 700 to a device or component external to the third semiconductor chip 700, such as the interposer substrate 800 and the stacked chip structure CS, whereas the bumps B4 formed on the lower surface of the third semiconductor chip 700 are attached onto the test pads TP to prevent the substrate 200 from being bent during the dicing process (shown in FIG. 6) separating the third semiconductor chip 700 from a semiconductor wafer. Therefore, when the semiconductor package 4000 is fabricated, the bumps B4 formed on the lower surface of the semiconductor chip 700 may not serve to electrically connect the third semiconductor chip 700 to the device external to the third semiconductor chip 700.

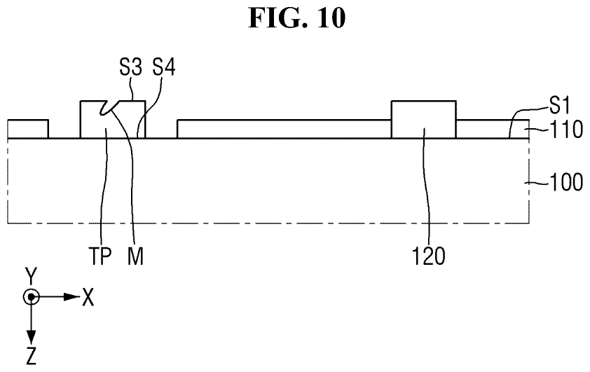

FIG. 9 is a flow chart illustrating a method for fabricating a bump of a semiconductor package according to some embodiments. FIGS. 10 to 19 are views illustrating intermediate steps to describe a method for fabricating bumps of a semiconductor package according to some embodiments.

Hereinafter, the method for fabricating the bumps B1, B2, B3 and B4 of the semiconductor package of the previous embodiments will be described with reference to FIGS. 9 to 19. In the following description, the method for fabricating the bump B4 and the bump B2, which are shown in the area II of FIG. 2, will be described as an example. The description of the method for fabricating the bump B2 may be equally applied to that of the method for fabricating the bumps B1 and B3. Also, in the following description, the upper surface or the lower surface may be based on the opposite direction of the first direction Z.

First, referring to FIGS. 9 and 10, a semiconductor chip 100 may be provided in which the passivation layer 110, the connection pad 120 and the test pad TP are formed on the first surface S1 of the semiconductor chip 100 (S100). In some embodiments, the semiconductor chip 100 may be in a state that the EDS test is completed. Therefore, the test probing mark M may be formed on the third surface S3 of the test pad TP.

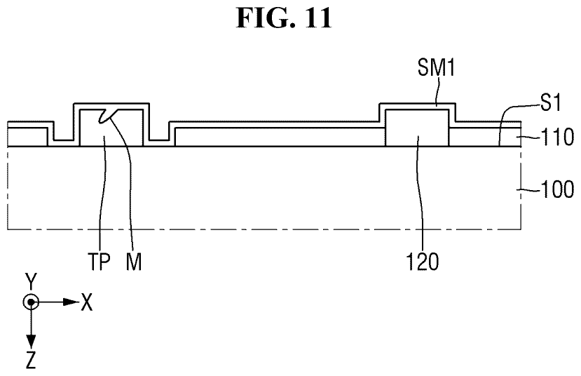

Subsequently, referring to FIGS. 9 and 11, a first seed material SM1 may be deposited on the first surface S1 of the semiconductor chip 100 (S101). At this time, the first seed material SM1 may be formed so as to cover the first surface S1 of the semiconductor chip 100, the upper surface of the passivation layer 110, the sides of the passivation layer 110, the upper surface of the test pad TP, the sides of the test pad TP, the upper surface of the connection pad 120 and the sides of the connection pad 120. Also, in accordance with some embodiments, when the test probing mark M is formed on the third surface S3 of the test pad TP, the first seed material SM1 may be formed to fill the lead-in portion of the test probing mark M.

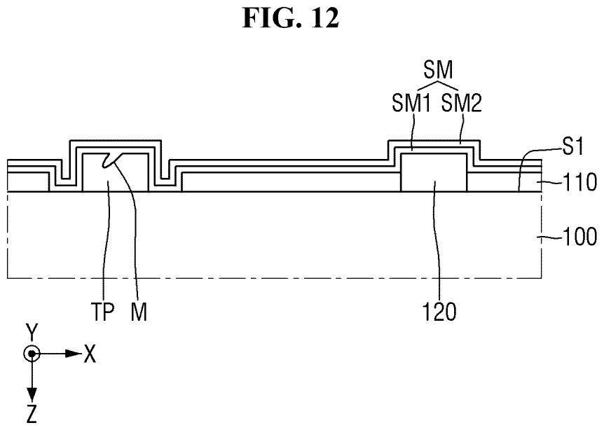

Then, referring to FIGS. 9 and 12, a second seed material SM2 may be deposited on the first seed material SM1 (S102). The second seed material SM2 may be formed as the second seed layer SL2 (shown in FIG. 3) in a subsequent process. When an electrolytic plating process is used in a subsequent process, the second seed material SM2 may act as a seed so that metal to be plated may be grown relatively easily.

Also, the first seed material SM1 may be formed as the first seed layer SL1 (shown in FIG. 3) in a subsequent process. The first seed material SM1 may serve to block diffusion of the second seed material SM2. The first seed material SM1 and the second seed material SM2 may be formed by a chemical vapor deposition (CVD) process, a physical vapor deposition (PVD) process or an atomic layer deposition (ALD) process.

In this way, before the bumps B4 and B2 are formed on the test pad TP and the connection pad 120, respectively, a seed material layer SM, which includes the first seed material SM1 and the second seed material SM2, may be formed to attach the bumps B4 and B2 onto the test pad TP and the connection pad 120 in a relatively stable manner.

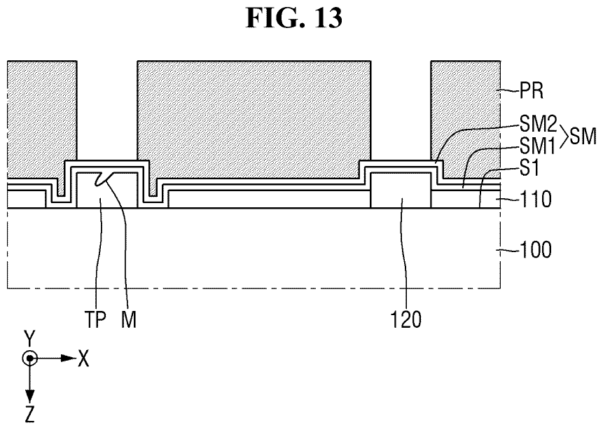

Subsequently, referring to FIGS. 9 and 13, a photoresist layer PR may be formed by coating a photoresist on the second seed material SM2 (S103). The photoresist layer PR may be formed to open or expose positions where the bumps B4 and B2 are to be formed in the semiconductor package 1000 of FIG. 3. The photoresist layer PR may be patterned through an exposure and development process performed after the photoresist layer PR is formed.

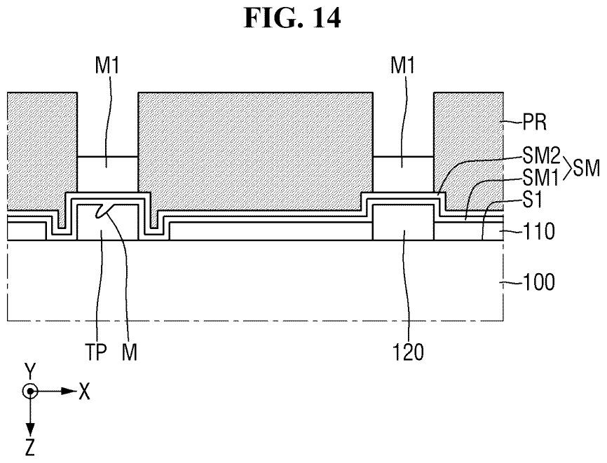

Subsequently, referring to FIGS. 9 and 14, first conductive materials M1 may be formed on the test pad TP and the connection pad 120, respectively (S104). At this time, an upper surface of the first conductive materials M1 may be formed to be lower than an upper surface of the photoresist layer PR. The first conductive materials M1 may be formed using electrolytic plating, CVD or PVD, and pillar portions P2 and P1 (shown in FIG. 3) may be finally formed.

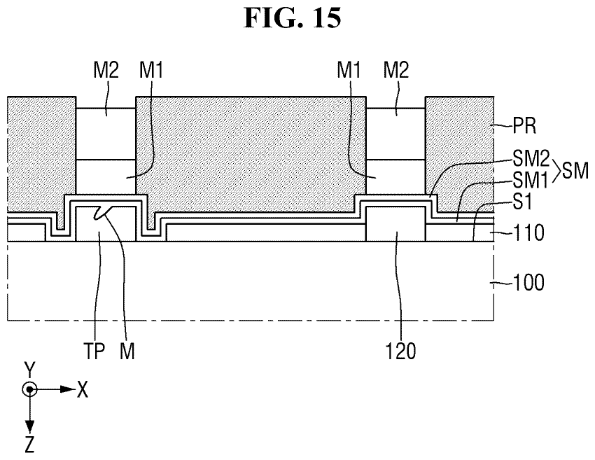

Then, referring to FIGS. 9 and 15, second conductive materials M2 may be formed on the first conductive materials M1, respectively (S105). The second conductive materials M2 may be solder materials. In FIG. 15, the upper surface of the second conductive materials M2 are shown as being formed to be lower than the upper surface of the photoresist layer PR, but the present disclosure is not limited thereto. For example, the second conductive materials M2 may be formed on the photoresist layer PR, and may be extended laterally on the photoresist layer PR. The second conductive materials M2 may be later subjected to a reflow process to form solder portions SD2 and SD1 (shown in FIG. 3) in the form of solder balls, respectively.

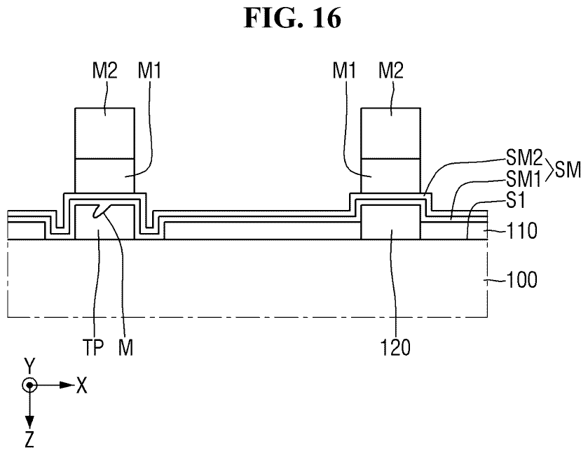

Next, referring to FIGS. 9 and 16, the photoresist layer PR may be removed (S106). The photoresist layer PR may be removed by a dry etching process or a wet etching process. For example, the photoresist layer PR may be removed using a strip process that includes ashing and cleaning.

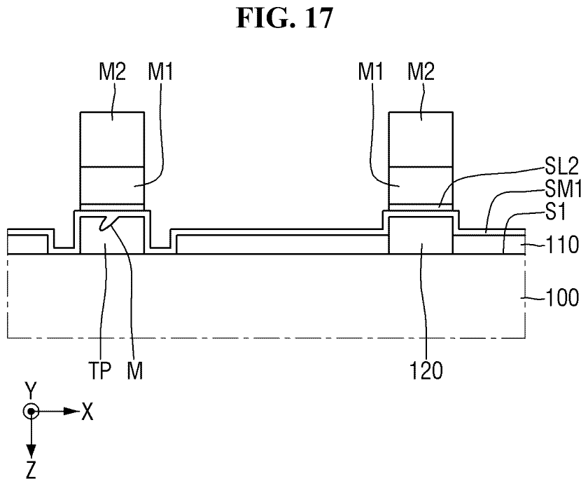

Then, referring to FIGS. 9 and 17, the second seed material SM2 may be etched (S107). The second seed material SM2 may be removed by dry etching, for example, a reactive ionic etch (RIE). As a result, the second seed material SM2 formed on the first surface S1 of the semiconductor chip 100 may be removed. However, the second seed layer SL2 may be formed in a state that the second seed material SM2 formed on the test pad TP and the connection pad 120 is not removed during etching.

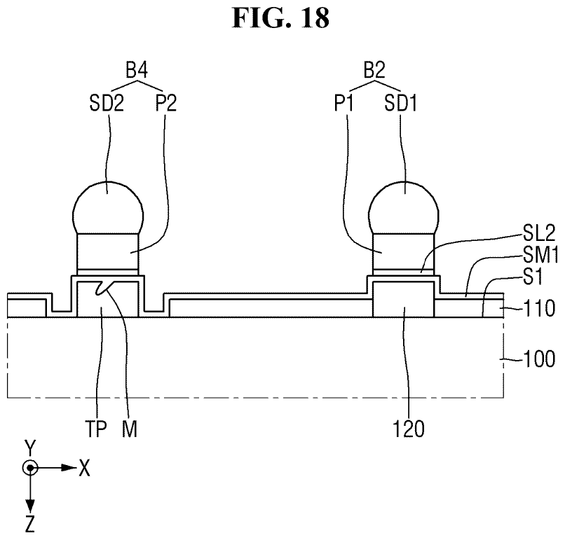

Next, referring to FIGS. 9 and 18, solder portions SD2 and SD1 in the form of solder balls may be formed through a reflow process (S108). The reflow process may be a soldering process for bonding the solder portions SD2 and SD1 to the external device. The reflow process may be performed at a temperature equal to or greater than a melting point of the solder portions SD2 and SD1, for example, at a temperature of 260° C. or more. The reflow process may be performed at an atmospheric pressure, and may be performed under a nitrogen (N₂) atmosphere. The reflow process may be performed for several minutes, for example, for 1 minute to 2 minutes. During reflow, the solder portions SD2 and SD1 may be melted to have fluidity, and may be formed in a ball shape by surface tension.

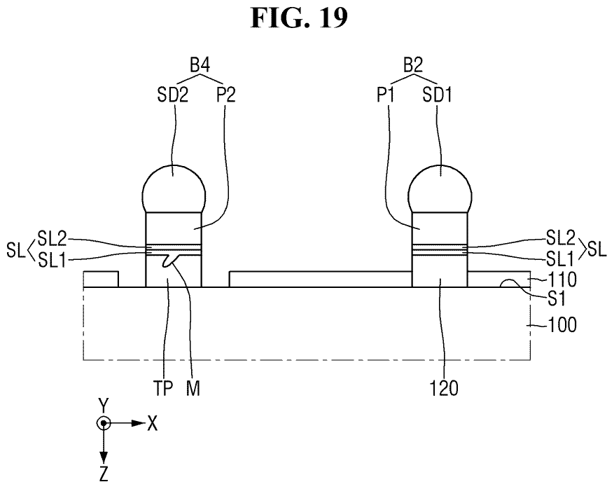

Next, referring to FIGS. 9 and 19, the first seed material SM1 may be etched (S109). Like the second seed material SM2, the first seed material SM1 may be removed by dry etching, for example, a reactive ionic etch (RIE) method. As a result, the first seed material SM1 formed on the first surface S1 of the semiconductor chip 100 may be removed, and finally the bump B4 and the bump B2 may be formed on the test pad TP and the connection pad 120, respectively. However, the first seed layer SL1 may be formed in a state that the first seed material SM1 formed on the test pad TP and the connection pad 120 is not removed during etching.

In this way, the process of forming the bump B4 on the test pad TP, which is not used in a packaging process, may be performed simultaneously with the process of forming the bumps B1, B2 and B3 on the connection pad 120.

While the present disclosure has been particularly illustrated and described with reference to some examples of embodiments thereof, it will be understood by those of ordinary skill in the art that various changes in form and detail may be made therein without departing from the scope of the present disclosure as defined by the following claims. The examples of embodiments provided herein should be considered in a descriptive sense only and not for purposes of limitation.

What is claimed is:

1. A semiconductor package comprising:
a semiconductor chip including a first surface and a second surface, which are opposite to each other in a first direction;
a plurality of first bumps in a first area on the first surface, the plurality of first bumps arranged along a second direction that intersects with the first direction;
a plurality of second bumps in a second area on the first surface, the plurality of second bumps arranged along the second direction and spaced apart from the plurality of first bumps in a third direction that intersects with the first direction and the second direction;
a first test pad in a third area on the first surface between the first area and the second area; and
a third bump on the first test pad,
wherein the first test pad is along an edge of the semiconductor chip in the third direction.

2. The semiconductor package of claim 1, wherein the first test pad is an electrical die sorting (EDS) test pad.

3. The semiconductor package of claim 2, wherein the first test pad includes a third surface and a fourth surface, which are opposite to each other in the first direction,
the third bump is on the third surface, and
a test probing mark is on the third surface.

4. The semiconductor package of claim 1, further comprising connection pads on the first surface, and through electrodes that extend into at least a portion of the semiconductor chip in the first direction, the through electrodes electrically connected to the connection pads.

5. The semiconductor package of claim 4, wherein the plurality of first bumps and the plurality of second bumps are on the connection pads, and are electrically connected to the connection pads and the through electrodes.

6. The semiconductor package of claim 1, wherein the third bump is electrically isolated from the first test pad.

7. The semiconductor package of claim 1, wherein upper surfaces of the plurality of first bumps, the plurality of second bumps and the third bump an equal distance from the first surface of the semiconductor chip.

8. The semiconductor package of claim 1, further comprising a plurality of fourth bumps in a fourth area on the first surface and arranged along the second direction and spaced apart from the plurality of second bumps in the third direction; and
a second test pad in a fifth area between the second area and the fourth area,
wherein the second test pad is along the edge of the semiconductor chip in the third direction.

9. The semiconductor package of claim 8, wherein the semiconductor chip includes a first edge and a second edge, which extend in length in the second direction and are spaced apart from each other in the third direction, and a third edge and a fourth edge, which extend in length in the third direction and are spaced apart from each other in the second direction, and
wherein the plurality of first bumps are along the first edge, and the plurality of fourth bumps are along the second edge.

10. The semiconductor package of claim 9, wherein the third bump is between the plurality of first bumps and the plurality of second bumps along the third edge or the fourth edge, and
a fifth bump is between the plurality of second bumps and the plurality of fourth bumps along the third edge or the fourth edge.

11. A semiconductor package comprising:
a semiconductor chip including a first surface and a second surface, which are opposite to each other in a first direction;
a test pad on the first surface;
a first bump on the test pad;
a second bump on the first surface and spaced apart from the first bump in a second direction that intersects with the first direction; and
a third bump on the first surface and spaced apart from the first bump in a direction opposite to the second direction,
wherein the first surface includes:
a first area that extends in a third direction that intersects with the first direction and the second direction;
a second area that extends in the third direction and is spaced apart from the first area in the second direction; and
a third area that extends in the third direction and is between the first area and the second area,
wherein the first bump, the second bump and the third bump are in the third area, the second area and the first area, respectively, and
wherein the test pad is along an edge of the semiconductor chip in the second direction.

12. The semiconductor package of claim 11, wherein a length in the first direction from the first surface to an upper surface of the third bump is greater than a length in the first direction from the first surface to an upper surface of the first bump.

13. The semiconductor package of claim 11, wherein the test pad is an electrical die sorting (EDS) test pad.

14. The semiconductor package of claim 13, wherein the test pad includes a third surface and a fourth surface, which are opposite to each other in the first direction,
wherein the fourth surface is at a level farther than the third surface from the first surface in the first direction, and
wherein the test pad includes a test probing mark that extends into the test pad from the third surface.

15. The semiconductor package of claim 14, further comprising a seed layer between the test pad and the first bump,
wherein the seed layer is in a portion of the test probing mark that extends into the test pad from the third surface of the test pad.

16. A semiconductor package comprising:
a base substrate;
a first semiconductor chip on the base substrate, including a first surface facing the base substrate and a second surface opposite to the first surface in a first direction;
a plurality of second semiconductor chips on the first semiconductor chip, each second semiconductor chip including a third surface and a fourth surface opposite to the third surface in the first direction, the fourth surface at a level farther than the third surface from the base substrate in the first direction; and
a first bump group between the base substrate and the first semiconductor chip,
wherein the first bump group includes:
first bumps spaced apart from each other in a second direction that intersects with the first direction; and
a second bump between the first bumps,
wherein the second bump is on a first test pad on the first surface, and
wherein the first test pad is along an edge of the first semiconductor chip in the second direction.

17. The semiconductor package of claim 16, further comprising a second bump group between the first semiconductor chip and one of the second semiconductor chips or between a pair second semiconductor chips,
wherein the second bump group includes:
third bumps spaced apart from each other in the second direction; and
a fourth bump between the third bumps,
wherein the fourth bump is on a second test pad on the third surface, and
wherein the second test pad is along an edge of a second semiconductor chip in the second direction.

18. The semiconductor package of claim 17, further comprising:
a first adhesive layer between the base substrate and the first semiconductor chip; and
a second adhesive layer between the first semiconductor chip and the second semiconductor chip or between each of second semiconductor chips,
wherein the first adhesive layer surrounds sides of the first bumps and the second bump, and
wherein the second adhesive layer surrounds sides of the third bumps and the fourth bump.

19. The semiconductor package of claim 17, wherein the fourth bump is electrically isolated from the first semiconductor chip and the second semiconductor chip.

20. The semiconductor package of claim 16, wherein the second bump is electrically isolated from the base substrate and the first semiconductor chip.
